(19) United States
(12) Patent Application Publication
(10) Pub. No.: US 2004/0094192 A1
(43) Pub. Date: May 20, 2004

(54) Thermal electric generator

(76) Inventor: Chin-Kuang Luo, Taichung City (TW)

Correspondence Address: TROP PRUNER & HU, PC, 8554 KATY FREEWAY, SUITE 100, HOUSTON, TX, 77024, US

(21) Appl. No.: 10/395,727

(22) Filed: Mar. 24, 2003

(30) Foreign Application Priority Data
Nov. 14, 2002 (TW) 091133425

(51) Int. Cl. H01L 35/00; H01L 37/00

(52) U.S. Cl. 136/203; 136/205

(57) ABSTRACT

In a thermal electric generator, a thermoelectric cooling device has a hot side in thermal communication with a heat collector that is disposed in thermal communication with a heat source. A heat sink is provided on a cold side of the thermoelectric cooling device. A heat-insulating layer is disposed between the heat collector and the heat sink, and has the thermoelectric cooling device embedded therein. The hot side of the thermoelectric cooling device receives heat energy from the heat collector so as to result in a temperature difference between the hot and cold sides. The thermoelectric cooling device generates an electrical current corresponding to the temperature difference.

### CROSS-REFERENCE TO RELATED APPLICATION

This application claims priority of Taiwanese Application No. 091133425, filed on Nov. 14, 2002.

### BACKGROUND OF THE INVENTION

1. Field of the Invention

The invention relates to a thermal electric generator, more particularly to a thermal electric generator that incorporates a thermoelectric cooling device.

2. Description of the Related Art

In a convention thermal electric generator, a thermoelectric cooling device is employed to generate an electrical current when operated in the Seebeck mode, as a result of a temperature difference between hot and cold sides. However, because no means is provided for supplying heat energy from a heat source in a stable and quick manner, an unstable temperature difference is often formed between the hot and cold sides.

### SUMMARY OF THE INVENTION

Therefore, the object of the present invention is to provide a thermal electric generator that permits formation of a relatively stable temperature difference between hot and cold sides of a thermoelectric cooling device.

According to the present invention, a thermal electric generator comprises:

a heat collector adapted to be disposed in thermal communication with a heat source;

a thermoelectric cooling device having a hot side in thermal communication with the heat collector, and

a cold side opposite to the hot side;

a heat sink provided on the cold side of the thermoelectric cooling device; and

a heat-insulating layer disposed between the heat collector and the heat sink and having the thermoelectric cooling device embedded therein.

The hot side of the thermoelectric cooling device receives heat energy from the heat collector so as to result in a temperature difference between the hot and cold sides. The thermoelectric cooling device generates an electrical current corresponding to the temperature difference.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic circuit block diagram illustrating the first preferred embodiment of a thermal electric generator according to the present invention;

FIG. 2 is a schematic sectional view showing the first preferred embodiment;

FIG. 3 is a schematic sectional view showing a thermoelectric cooling device of the first preferred embodiment; and

FIG. 4 is a schematic sectional view showing the second preferred embodiment of a thermal electric generator according to the present invention.

### DETAILED DESCRIPTION OF THE PREFERRED EMBODIMENTS

Before the present invention is described in greater detail, it should be noted that like elements are denoted by the same reference numerals throughout the disclosure.

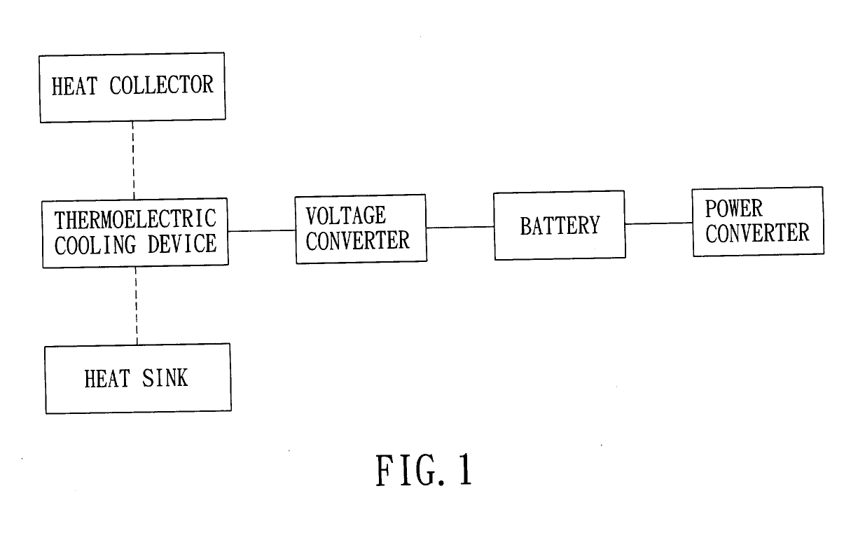

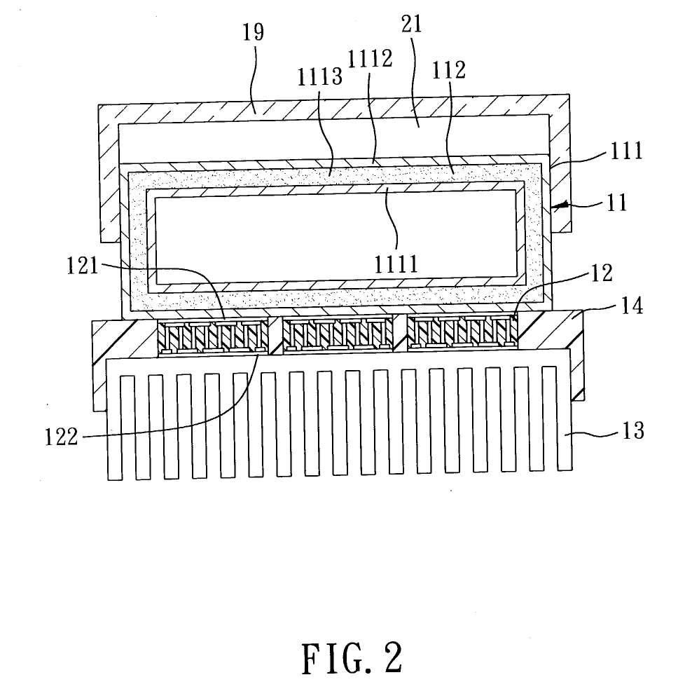

Referring to FIGS. 1 and 2, the preferred embodiment of a thermal electric generator according to the present invention is shown to include a heat collector 11, a thermoelectric cooling device 12, a heat sink 13, a heat-insulating layer 14, a voltage converter 15, a battery 16, and a power converter 17.

The heat collector 11 is adapted to be disposed in thermal communication with a heat source (not shown). In this embodiment, the heat collector 11 is adapted to collect solar energy. In other embodiment, the heat collector 11 may be configured to collect heat energy from an incinerator or from high temperature flue gas. In this embodiment, the heat collector 11 includes a hollow heat-conducting member 111 that has inner and outer walls 1111, 1112 confining an enclosed chamber 1113 therebetween. Preferably, the enclosed chamber 1113 is a sealed vacuum chamber, and is filled with a thermally conductive material, such as water, methanol, acetone, ammonia, nitrogen, sodium, lithium, or mixtures thereof.

The thermal electric generator further includes a transparent glass cap 19 capped on the heat collector 11 for focusing solar energy. The glass cap 19 cooperates with the heat collector 11 so as to confine a sealed vacuum chamber 21 therebetween for containing heat energy therein.

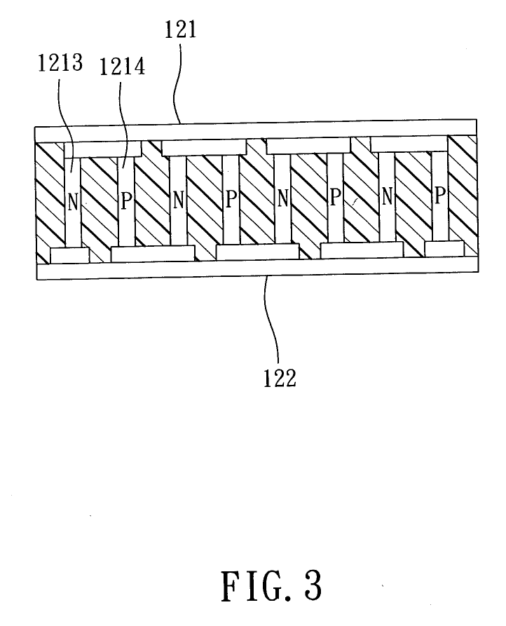

The thermoelectric cooling device 12 includes a plurality of n-type and p-type thermoelements 1213, 1214, as shown in FIG. 3, and has a hot side 121 in thermal communication with the outer wall 1112 of the heat-conducting member 111 of the heat collector 11, and a cold side 122 opposite to the hot side 121.

The heat sink 13 is provided on the cold side 122 of the thermoelectric cooling device 12 for dissipating heat at the cold side 122 of the thermoelectric cooling device 11 when the thermoelectric cooling device 11 is operated in the Seebeck mode.

The heat-insulating layer 14, which is made of a ceramics material or a heat-insulating adhesive, is disposed between the heat collector 11 and the heat sink 13, and has the thermoelectric cooling device 12 embedded therein for insulating thermal conduction between the hot and cold sides 121, 122 of the thermoelectric cooling device 11.

When the thermoelectric cooling device 12 is operated in the Seebeck mode, the hot side 121 receives heat energy from the heat collector 11 so as to result in a temperature difference between the hot and cold sides 121, 122. As such, the thermoelectric cooling device 12 generates an electrical current corresponding to the temperature difference. The voltage converter 15 is connected electrically to the thermoelectric cooling device 12 and converts the electrical current generated by the thermoelectric cooling device 12 into a direct current voltage, such as 12 volts or 24 volts.

The battery 16 is coupled electrically to the voltage converter 15 and is charged by the electrical current generated by the thermoelectric cooling device 12.

The power converter 17, such as a direct current-to-alternating current converter, is coupled electrically to the battery 16 for converting direct current power stored in the battery 16 into an alternating current power.

Furthermore, the thermal electric generator of the present invention can be operated in a cold place. Preferably, during winter, the hot side 121 of the thermoelectric cooling device 12 can be kept at room temperature (about 5 to 10° C.), while the cold side 122 of the thermoelectric cooling device 12 can be exposed to the outside environment having a temperature of about −5° C. As such, a temperature difference between the hot and cold sides 121, 122 can be ensured.

In view of the foregoing, due to the presence of the heat collector 11 and the heat-insulating layer 4 in the generator of the present invention, a relatively stable temperature difference between the hot and cold sides 121, 122 of the thermoelectric cooling device 12 can be ensured.

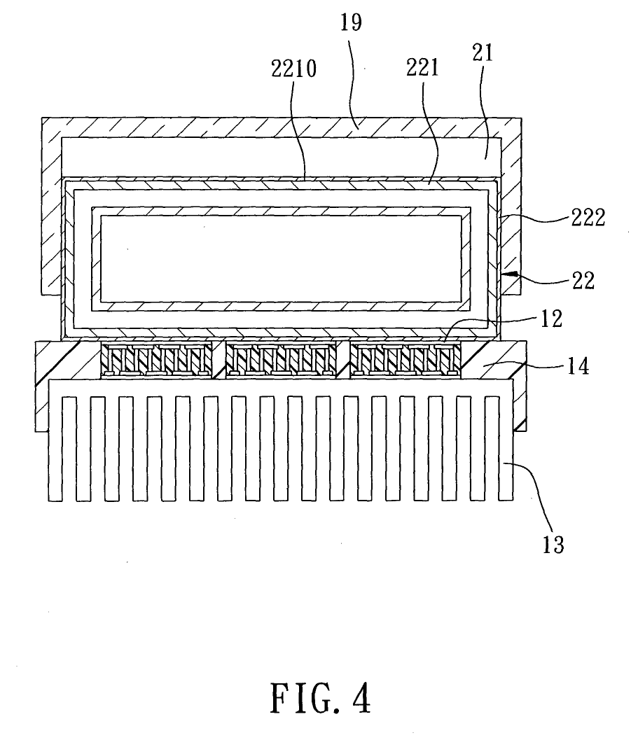

FIG. 4 illustrates the second preferred embodiment of a thermal electric generator according to this invention, which is a modification of the first preferred embodiment. Unlike the previous embodiment, the heat-conducting member 221 of the heat collector 22 has a surface 2210 coated with a thermally conductive material. In this embodiment, the thermally conductive material is a superconductor.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

I claim:

1. A thermal electric generator comprising:
a heat collector adapted to be disposed in thermal communication with a heat source;
a thermoelectric cooling device having a hot side in thermal communication with said heat collector, and a cold side opposite to said hot side;
a heat sink provided on said cold side of said thermoelectric cooling device; and
a heat-insulating layer disposed between said heat collector and said heat sink and having said thermoelectric cooling device embedded therein;
wherein said hot side of said thermoelectric cooling device receives heat energy from said heat collector so as to result in a temperature difference between said hot and cold sides, said thermoelectric cooling device generating an electrical current corresponding to the temperature difference.

2. The thermal electric generator as claimed in claim 1, wherein said thermoelectric cooling device includes a plurality of n-type and p-type thermoelements.

3. The thermal electric generator as claimed in claim 1, wherein said heat collector includes a hollow heat-conducting member that has inner and outer walls confining an enclosed chamber therebetween, said hot side of said thermoelectric device being in thermal contact with said outer wall of said heat-conducting member.

4. The thermal electric generator as claimed in claim 3, wherein said enclosed chamber is filled with a thermally conductive material.

5. The thermal electric generator as claimed in claim 3, wherein said enclosed chamber is a sealed vacuum chamber.

6. The thermal electric generator as claimed in claim 5, wherein said enclosed chamber is filled with a thermally conductive material.

7. The thermal electric generator as claimed in claim 1, wherein said heat-conducting member has a surface coated with a thermally conductive material.

8. The thermal electric generator as claimed in claim 1, wherein said heat collector is adapted to collect solar energy.

9. The thermal electric generator as claimed in claim 8, further comprising a transparent glass cap capped on said heat collector and cooperating with said heat collector so as to confine a sealed vacuum chamber therebetween.

10. The thermal electric generator as claimed in claim 1, wherein said heat collector is adapted to collect heat energy from an incinerator.

11. The thermal electric generator as claimed in claim 1, wherein said heat collector is adapted to collect heat energy from high temperature flue gas.

12. The thermal electric generator as claimed in claim 1, further comprising a battery coupled to said thermoelectric cooling device and charged by the electrical current generated by said thermoelectric cooling device.

13. The thermal electric generator as claimed in claim 12, further comprising a voltage converter that interconnects electrically said battery and said thermoelectric cooling device.

14. The thermal electric generator as claimed in claim 12, further comprising a power converter coupled electrically to said battery.
